(19) United States
(12) Patent Application Publication
(10) Pub. No.: US 2009/0190428 A1
(43) Pub. Date: Jul. 30, 2009

(54) NONVOLATILE SEMICONDUCTOR MEMORY DEVICE

(76) Inventor: Junichi Kato, Kyoto (JP)

Correspondence Address: MCDERMOTT WILL & EMERY LLP, 600 13TH STREET, NW, WASHINGTON, DC, 20005-3096, US

(21) Appl. No.: 12/256,775

(22) Filed: Oct. 23, 2008

(30) Foreign Application Priority Data
Jan. 30, 2008 (JP) 2008-019065

(51) Int. Cl. G11C 5/14

(52) U.S. Cl. 365/228

(57) ABSTRACT

In a semiconductor device equipped with a nonvolatile memory, using a simple configuration, a write operation and the like are reliably made feasible even when stability of power supply from an external component is inhibited. The semiconductor device includes a nonvolatile memory core including a nonvolatile memory and a switch for switching a power supply mode for supplying power to the nonvolatile memory core between a first mode in which power is supplied from an external power supply and a second mode in which power is supplied from an accumulation device used as a back-up power supply. The nonvolatile memory core outputs a status signal indicating an operation state of the nonvolatile memory core, and the switch switches the power supply mode according to an operation state of the nonvolatile memory core that the status signal indicates.

### CROSS-REFERENCE TO RELATED APPLICATION

This application claims priority under 35 U.S.C. §119(a) on Japanese Patent Application No. 2008-019065 filed on Jan. 30, 2008, the entire contents of which are hereby incorporated by reference.

### BACKGROUND OF THE INVENTION

1. Field of the Invention

The present invention relates to a nonvolatile semiconductor memory device equipped with a nonvolatile memory such as a flash memory and the like, and more particularly relates to a technique for preventing inconveniences which occur when stability of external power supply is inhibited.

2. Description of the Related Art

In a nonvolatile semiconductor memory such as flash memory and the like, information is recorded or rewritten by electrical means. Therefore, while a write or rewrite operation is performed, necessary power has to be externally supplied at all the time. However, there might be cases where power supply is accidentally cut off or unexpected noise is applied. If no measure is taken to cope with those factors that hinder stable power supply, inaccurate data might not be recoreded or the memory might be destroyed.

As a technique to prevent such situations, in Patent Document 1, a back-up power supply for flash memory systems is disclosed. According to Patent Document 1, when a power supply loss is detected, a power supply bus is disconnected from a flash memory system and a back-up controller controls a power flow from a storage capacitor to the flash memory system. The power supplied by the storage capacitor allows the flash memory system to complete erasure and write operations.

Patent Document 2 discloses a method for performing writing to a memory in a safe manner against power supply cut. According to Patent Document 2, when a power supply cut is detected during a write operation from a CPU to an EEPROM, power supplied by a capacitor is used until the CPU safely completes the write operation and then the memory system is shut down.

Patent Document 3 discloses a method in which when data is being written in a flash memory, data to be written is temporarily stored in a buffer memory and then the data in the buffer memory is written in the flash memory. According to this method, after transferring data to the buffer memory, the system can execute some other operation while the data is stored in the flash memory.

Patent Document 4 discloses a method for allowing correct information to be written even when power supply is cut off. According to a technique of Patent Document 4, even when power is turned OFF when data is being written, it is possible to ensure data being stored in an external memory device in a right state. Moreover, a back-up power supply for protecting an operation of a computer system while a power supply is OFF does not have to be provided and files do not have to be duplexed. Therefore, the system can be formed to have an economical configuration and usability of the external memory device is not reduced.

(Patent Document 1) Japanese Translation of PCT International Application No. 2005-532620

(Patent Document 2) Japanese Laid-Open Publication No. 11-149419

(Patent Document 3) Japanese Laid-Open Publication No. 62-172597

(Patent Document 4) Japanese Laid-Open Publication No. 1-191246

In a nonvolatile semiconductor memory device equipped with a nonvolatile memory, when it is required to complete a write operation within a limited time and ensure that written information is correct, the above-described known technique is not necessarily effective.

According to the known technique, using a back-up power supply and a detection circuit for detecting a voltage cut, discontinuation of a write operation due to a power supply cut is prevented. However, when the system returns to a write operation from a halt state, whether or not necessary data for the write operation has been written has to be judged. If the data has not been written, a flash memory or the like is refreshed once and a rewrite operation has to be performed. If the series of operations is performed, there might be cases where the known technique can not be used in a system requiring the completion of a write operation within a limited time. Moreover, because the detection circuit for detecting a voltage cut is used, a device configuration becomes complicated.

### SUMMARY OF THE INVENTION

It is therefore an object of the present invention to make write operation and the like feasible even when stability of external power supply is inhibited using a simple configuration in a nonvolatile semiconductor memory device.

The present invention is directed to a nonvolatile semiconductor memory device including: a nonvolatile memory core including a nonvolatile memory; and a switch for switching a power supply mode for supplying power to the nonvolatile memory core between a first mode in which power is supplied from an external power supply and a second mode in which power is supplied from an accumulation device used as a back-up power supply. In the nonvolatile semiconductor memory device, the nonvolatile memory core outputs a status signal indicating whether or not the nonvolatile memory core is in a specific operation state, and the switch receives the status signal and sets, when the status signal indicates that the nonvolatile memory core is in the specific operation state, the power supply mode to be the second mode.

According to the present invention, the power supply mode for supplying power to the nonvolatile memory core can be switched between the first mode in which power is supplied from the external power supply and the second mode in which power is supplied from the accumulation device used as a back-up power supply. The nonvolatile memory core outputs a status signal indicating whether or not the nonvolatile memory core is in a specific operation state and, when the status signal indicates that the nonvolatile memory core is in the specific operation state, the switch sets the power supply mode to be the second mode. Thus, when the nonvolatile memory core is in the specific operation state, setting of the second mode in which power is supplied from the accumulation device can be achieved according to the status signal. Accordingly, for example, power supply can be controlled such that power is supplied from the accumulation device while the nonvolatile memory core executes a write operation. Therefore, even when stability of the external power supply is inhibited, a write operation is reliably feasible at all the time and there is no need to provide a detection circuit for detecting a voltage cut and the like.

According to the present invention, without providing devices such as a detection circuit for detecting a voltage cut and the like, it is possible to reliably make a write operation and the like feasible at all the time even when stability of an external power supply is inhibited.

### BRIEF DESCRIPTION OF THE DRAWINGS

FIG. 1 is a block diagram illustrating a configuration of a semiconductor device and peripheral elements of the semiconductor device according to one embodiment of the present invention.

FIG. 2 is a condition table showing an exemplary operation of a switch in the configuration of FIG. 1.

FIG. 3 is a condition table showing another exemplary operation of the switch in the configuration of FIG. 1.

FIG. 4 is a block diagram illustrating a configuration in which external switch control is made feasible.

FIG. 5 is a block diagram illustrating a configuration in which an accumulation device and a nonvolatile memory core are provided in the same semiconductor chip.

FIG. 6 is a cross-sectional view illustrating a configuration in which an accumulation device is stacked on a semiconductor chip including a memory core.

### DESCRIPTION OF THE PREFERRED EMBODIMENTS

Hereafter, embodiments of the present invention will be described with reference to the accompanying drawings.

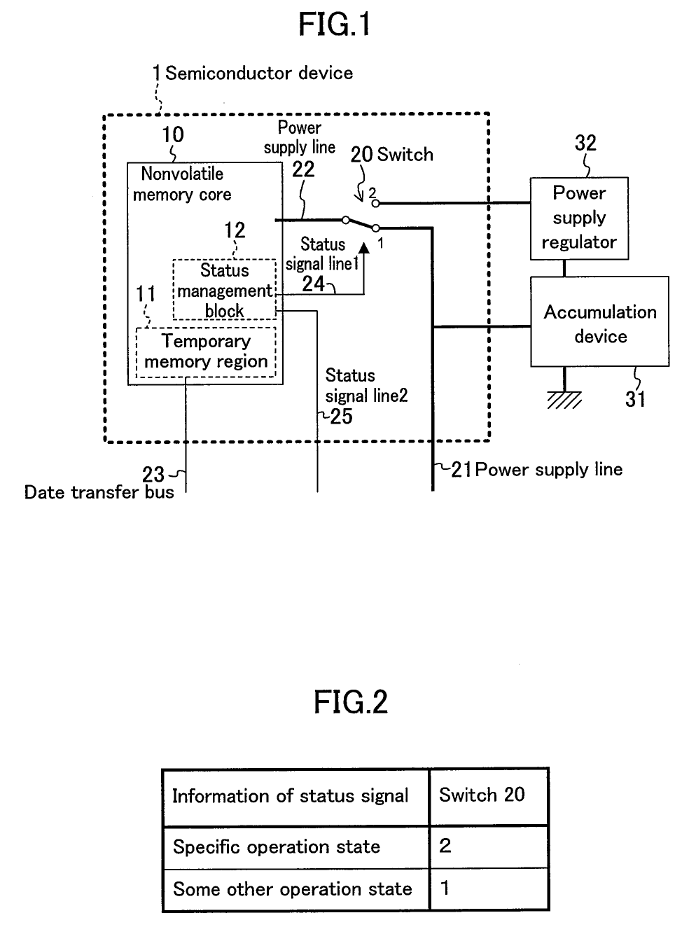

FIG. 1 is a block diagram illustrating a configuration of a semiconductor device (nonvolatile semiconductor memory device) and peripheral elements of the semiconductor device according to one embodiment of the present invention. In FIG. 1, a semiconductor device 1 includes a nonvolatile memory core 10 such as a flash memory core or the like. The nonvolatile memory core 10 includes a flash memory as an example of nonvolatile memories. On the periphery of the semiconductor device 1, an accumulation device 31 which is used as a back-up power supply and a power supply regulator 32 are provided. The power supply regulator 32 converts power generated when charges accumulated in the accumulation device 31 are released into a voltage with which the nonvolatile memory core 10 can be operated and supplies the voltage to the nonvolatile memory core 10.

The semiconductor device 1 also includes a switch 20 for switching a mode of power supply to the nonvolatile memory core 10. The switch 20 has two input terminals and one output terminal. One of the input terminals is connected to a power supply line 21 for supplying power from an external power supply and the other of the input terminals is connected to power supply regulator 32. The output terminal is connected to a power supply line 22 for supplying power to the nonvolatile memory core 10. That is, the switch 20 can switch the power supply mode between a first mode in which power is supplied from the external power supply and a second mode in which power is supplied from the accumulation device 31. The power supply line 21 for supplying power from the external power supply is also connected to the accumulation device 31.

A data transfer bus 23 and status signal lines 24 and 25 are connected to the nonvolatile memory core 10. The data transfer bus 23 transfers data when a write operation or a read operation is performed. The nonvolatile memory core 10 outputs a status signal for indicating an operation state of the nonvolatile memory core 10 to the status signal lines 24 and 25. To output the status signal, a status management block 12 is preferably provided in the nonvolatile memory core 10. The status signal line 24 is used as a control signal line for the switch 20. The switch 20 receives the status signal and switches a power supply mode according to the operation state of the nonvolatile memory core 10 which is indicated by the status signal.

Next, the operation of the configuration of FIG. 1 will be described.

FIG. 2 is a condition table showing an exemplary operation of the switch 20. In the example shown in FIG. 2, a status signal indicates whether or not the nonvolatile memory core 10 is in a specific operation state. When the status signal indicates that the nonvolatile memory core 10 is in the specific operation state, the switch 20 selects the second mode in which power is supplied from the accumulation device 31 and, on the other hand, when the status signal indicates any other state, the switch 20 selects the first mode in which power is supplied from the external power supply.

Now, a state where a write operation is executed is assumed as the specific operation state. Specifically, when a write operation is started, the switch 20 receives a status signal and switches the power supply mode to the second mode in which power is supplied from the accumulation device 31. Thus, the power supply system is disconnected from external components during a write operation of the nonvolatile memory core 10, so that inhibition due to external factors such as power supply cut, noise and the like can be avoided. Accordingly, a write operation can be reliably performed, regardless of an external power supply state. Moreover, in the configuration of FIG. 1, a special mechanism for sensing external factors such as a power supply cut, noise and the like is not needed. Therefore, the configuration of the device can be simplified.

For example, a temporary memory region 11 in which written information is temporarily stored is provided in the nonvolatile memory core 10. Written information is transferred to the temporary memory region 11 beforehand and then the written information is written into a flash memory from the temporary memory region 11. At a time when the transfer of the written information to the temporary memory region 11 is completed, the nonvolatile memory core 10 starts writing from the temporary memory region 11 to the flash memory. During the write operation, the nonvolatile memory core 10 outputs a status signal indicating that the nonvolatile memory core 10 is in the specific operation state. Thus, while writing from the temporary memory region 11 to the flash memory is performed, power is supplied by the accumulation device 31, so that inhibition due to external factors such as a power supply cut, noise and the like can be avoided.

Accordingly, when this method is adopted, it is determined, at a time when data transfer to the temporary memory region 11 is completed, that data write to the flash memory is to be reliably executed. Therefore, in a system employing this technique, at the completion of data transfer to the temporary memory region 11, it can be presumed that a write operation has been performed. In the system, presuming that writing is completed, an arbitrary process can be conducted without waiting for the completion of writing from the temporary memory region 11 to the flash memory.

In the configuration of this embodiment, the connection of an accumulation device is necessary. As the accumulation device, a device capable of storing a necessary amount of power for writing data in the flash memory may be used. For example, when a write operation is completed by flowing a current of 100 uA for 10 us in a memory transistor constituting a flash memory cell, generally, a charge amount of 1 nC per bit is required. For example, if a supply voltage is 10 V and a 1 uF accumulation device is prepared, the charge amount of the accumulation device is 10 uC, and thus a write operation for about 1 kbyte information can be completed. The capacity of the accumulation device may be arbitrarily set according to the amount of information to be written.

In the above-described example, a technique in which power is supplied from the accumulation device 31 during writing has been described. However, even when some other operation than writing is performed, power supply from the accumulation device 31 can be selected in the same manner. For example, when it is desired to select power supply from the accumulation device 31 in an erasure operation of the flash memory, the nonvolatile memory core 10 may be configured so as to output, as a status signal, a signal indicating that the nonvolatile memory core 10 is in a specific operation state while the erasure operation of the flash memory is executed.

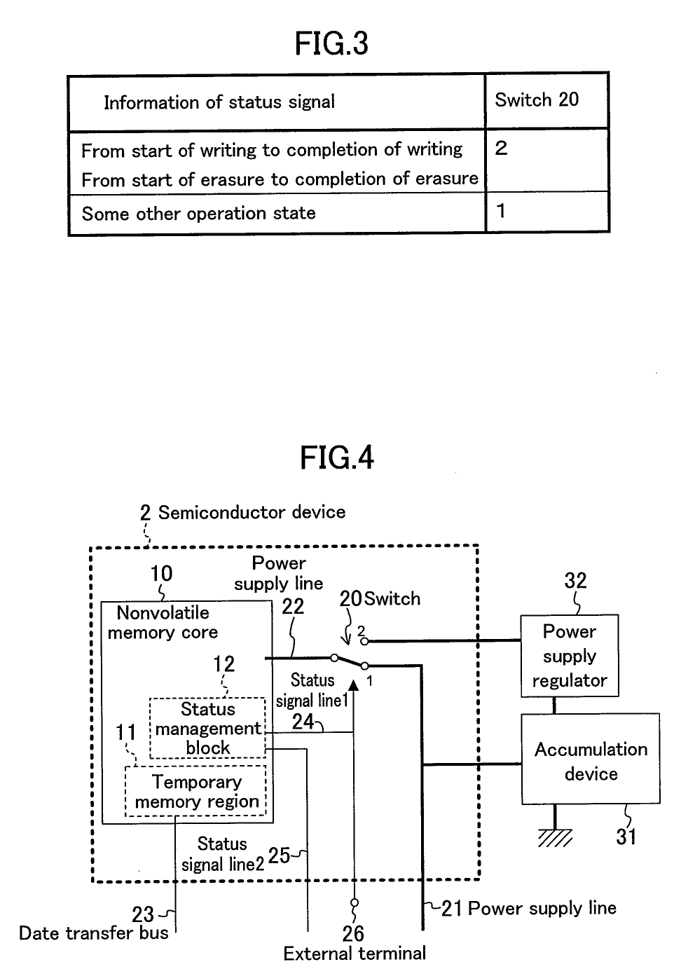

FIG. 3 is a condition table illustrating an exemplary operation of the switch 20. In the example of FIG. 3, when the nonvolatile memory core 10 executes a write operation or an erasure operation, it is assumed that the nonvolatile memory core 10 is in a specific operation state. Specifically, when the status signal indicates that a write operation or an erasure operation is executed, the switch 20 selects the second mode in which power is supplied from the accumulation device 31 and, on the other hand, when the status signal indicates some other state, the switch 20 selects the first mode in which power is supplied from the external power supply.

If the configuration in which power supply from the accumulation device 31 is executed during erasure is adopted, in a region of a flash memory in which information is already written, the information can be erased and then new information can be written. By using this technique, a region in an erasure state does not have to be prepared before a start of a write operation and simple control can be performed.

In the configuration of FIG. 1, the switch 20 is controlled according to a status signal output from the nonvolatile memory core 10. However, as shown in FIG. 4, an external terminal 26 for receiving a signal for controlling the switch 20 may be provided so that setting of power supply mode using switch 20 can be externally controlled. The switch 20 is configured so as to be capable of switching the power supply mode according to a signal given to the external terminal 26. With this configuration, a status can be managed outside of the semiconductor device 2 and the switch 20 can be externally controlled. By using this technique, the power supply mode can be selectively controlled at an external system side, so that switching according to a necessary capacity becomes possible.

Whether or not a sufficient amount of charges for performing writing to the accumulation device 31 is accumulated is preferably checked at a time of start of writing. For example, a mechanism for detecting a charge amount of the accumulation device 31 is provided so that only if a sufficient amount of charges are accumulated in the accumulation device 31 at a time of start of writing, the switch 20 switches the power supply mode to perform power supply from the accumulation device 31. When a capacitor is used, the amount of accumulated charges in the accumulation device 31 can be detected in a simple manner by measuring a voltage value of the capacitor. If a sufficient charge accumulation time is given before a start of writing, a mechanism for detecting the charge amount of the accumulation device 31 does not necessarily have to be provided.

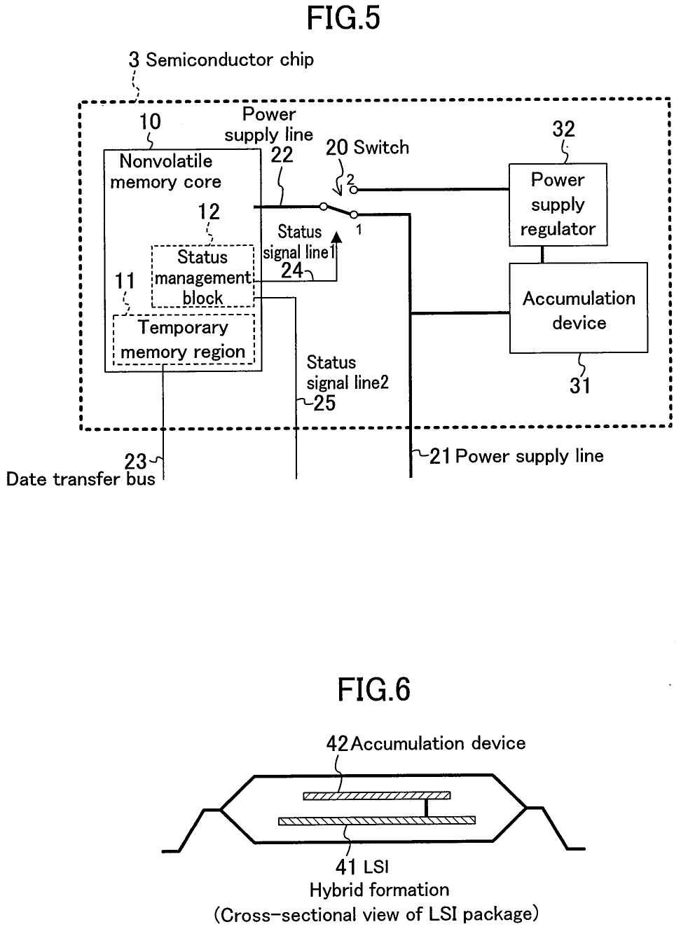

As shown in FIG. 5, the accumulation device 31 and the power supply regulator 32 may be provided together in a semiconductor chip 3 in which the nonvolatile memory core 10 is configured. Thus, necessary functions are mounted in a single semiconductor chip 3 and a product according to the present invention can be formed in a single package. Accordingly, in forming a set, a simplified component formation can be obtained. Moreover, operation verification can be conducted in each package and thus operation vilification after set mounting is not needed.

As shown in FIG. 6, a configuration in which an accumulation device 42 is stacked on a semiconductor chip (LSI) 41 in which a nonvolatile memory core is formed may be adopted. In this configuration, a product according to the present invention can be also configured in a single package. In this configuration, the accumulation device 42 can be formed so that the capacity of the accumulation device 42 is not constrained by a substrate area of the semiconductor chip 41.

A nonvolatile semiconductor memory device according to the present invention allows a write operation or the like to be reliably performed at all the time. Therefore, for example, the inventive nonvolatile semiconductor memory device can be effectively used for an IC card or the like which requires reliable write operation of necessary information within a limited time.

What is claimed is:

1. A nonvolatile semiconductor memory device comprising:
a nonvolatile memory core including a nonvolatile memory; and
a switch for switching a power supply mode for supplying power to the nonvolatile memory core between a first mode in which power is supplied from an external power supply and a second mode in which power is supplied from an accumulation device used as a back-up power supply,
wherein the nonvolatile memory core outputs a status signal indicating whether or not the nonvolatile memory core is in a specific operation state, and
the switch receives the status signal and sets, when the status signal indicates that the nonvolatile memory core is in the specific operation state, the power supply mode to be the second mode.

2. The nonvolatile semiconductor memory device of claim 1, wherein the nonvolatile memory core has a temporary memory region in which written information is temporarily stored and outputs as the status signal, during execution of a write operation from the temporary memory region to the nonvolatile memory, a signal indicating that the nonvolatile memory core is in the specific operation state.

3. The nonvolatile semiconductor memory device of claim 1, wherein the nonvolatile memory core outputs as the status signal, during execution of an erasure operation to the nonvolatile memory, a signal indicating that the nonvolatile memory core is in the specific operation state.

4. The nonvolatile semiconductor memory device of claim 1, further comprising an external terminal for receiving a signal to control the switch,
wherein the switch is so configured to be capable of switching the power supply mode according to the signal given to the external terminal.

5. The nonvolatile semiconductor memory device of claim 1, wherein the accumulation device is provided in a semiconductor chip in which the nonvolatile memory core is formed.

6. The nonvolatile semiconductor memory device of claim 1, wherein the accumulation device is stacked on a semiconductor chip in which the nonvolatile memory core is formed.
